(19) United States
(12) Patent Application Publication
(10) Pub. No.: US 2024/0280484 A1
(43) Pub. Date: Aug. 22, 2024

(54) ANGLE RESOLVED REFLECTOMETRY FOR THICK FILMS AND HIGH ASPECT RATIO STRUCTURES

(71) Applicant: KLA Corporation, Milpitas, CA (US)

(72) Inventors: David Y. Wang, Santa Clara, CA (US); Kevin Peterlinz, Fremont, CA (US)

(21) Appl. No.: 18/467,371

(22) Filed: Sep. 14, 2023

Related U.S. Application Data
(60) Provisional application No. 63/446,049, filed on Feb. 16, 2023.

(51) Int. Cl. G01N 21/55; G01B 11/06; G01N 21/21

(52) U.S. Cl. CPC G01N 21/55; G01B 11/06; G01N 21/21; H01L 22/12

(57) ABSTRACT

The system includes a light source configured to emit light at one or more wavelengths, one or more angles of incidence (AOI), and one or more azimuths; a polarization assembly configured to produce one or more polarization states of the light; a main objective configured to focus the light in the one or more polarization states onto a target that reflects the light; an analyzer assembly configured to analyze one or more polarization states of the light reflected from the target; a detector configured to detect the light reflected from the target and generate an output signal based on the detected light; and a processor configured to generate a measurement of the target based on the output signal produced at the one or more polarization states, the one or more wavelengths, the one or more AOIs, and the one or more azimuths.

### CROSS-REFERENCE TO RELATED APPLICATIONS

This application claims priority to the provisional patent application filed Feb. 16, 2023 and assigned U.S. App. No. 63/446,049, the disclosure of which is hereby incorporated by reference.

### FIELD OF THE DISCLOSURE

This disclosure relates to semiconductor metrology.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Metrology processes are used at various steps during semiconductor manufacturing to monitor and control the process. Metrology processes are different than inspection processes in that, unlike inspection processes in which defects are detected on wafers, metrology processes are used to measure one or more characteristics of the wafers that cannot be determined using existing inspection tools. Metrology processes can be used to measure one or more characteristics of wafers such that the performance of a process can be determined from the one or more characteristics. For example, metrology processes can measure a dimension (e.g., line width, thickness, etc.) of features formed on the wafers during the process. In addition, if the one or more characteristics of the wafers are unacceptable (e.g., out of a predetermined range for the characteristic(s)), the measurements of the one or more characteristics of the wafers may be used to alter one or more parameters of the process such that additional wafers manufactured by the process have acceptable characteristic(s).

In flash memory production, there is a growing demand for metrology of thick films, high aspect ratio (HAR) structures, and large pitch targets. Spectroscopic ellipsometry (SE), spectroscopic reflectometry (SR), and beam profile reflectometry (BPR) are techniques in film and critical dimension (CD) metrology, where target characteristics are determined by analyzing the light reflecting off the target, at different wavelengths, angle of incidence (AOI) or polarization states. 3D structures are more complicated to measure, as more wavelengths, polarization states, and angle information is needed to characterize a wide diversity of 3D structures. Existing systems have limitations that affect measurement diversity, sensitivity, and/or throughput. In one example, SE and SR systems can typically handle many wavelengths and polarization states, but they have limited AOI range-, which reduces measurement diversity. In another example, some SE systems have a relatively large AOI range by moving the stage or optics and sampling one AOI at a time. These SE systems are typically too slow for high-volume production. In another example, some 1-D BPR systems sample a x-slice and a y-slice of the pupil. These systems also lack measurement diversity for HAR structures. In another example, some 2-D BPR systems capture the full pupil but have a limited field of view of the target. These systems cannot receive all the reflected light from the HAR structures and lack measurement sensitivity.

Therefore, what is needed is a 2-D BPR system that is optimized for measurements of thick films, HAR structures, and large pitch layers with fast time to results for large wavelength and angle ranges.

### BRIEF SUMMARY OF THE DISCLOSURE

An embodiment of the present disclosure provides a system. The system may comprise a light source. The light source may be configured to emit light along an illumination path at one or more wavelengths, one or more angles of incidence (AOI), and one or more azimuths.

The system may further comprise a polarization assembly disposed in the illumination path. The polarization assembly may be configured to produce one or more polarization states of the light.

The system may further comprise a main objective disposed in the illumination path. The main objective may be configured to focus the light in the one or more polarization states onto a target. The target may be configured to reflect the light along a collection path. The main objective may be further configured to collect the light reflected from the target.

The system may further comprise an analyzer assembly disposed in the collection path. The analyzer assembly may be configured to analyze one or more polarization states of the light reflected from the target.

The system may further comprise a detector disposed in the collection path. The detector may be configured to detect the light reflected from the target and generate an output signal based on the detected light.

The system may further comprise a processor in electronic communication with the detector. The processor may be configured to generate a measurement of the target based on the output signal produced at the one or more polarization states, the one or more wavelengths, the one or more AOIs, and the one or more azimuths.

In some embodiments, the system may further comprise a collection pupil disposed in the collection path. The collection pupil may be configured to collect the light reflected from the target. An x-y position of the light collected on the collection pupil may correspond to a subset of the one or more AOIs and the one or more azimuths.

In some embodiments, the detector may be conjugate with the collection pupil. The detector may be configured to image each x-y position of the light collected on the collection pupil.

In some embodiments, the one or more wavelengths of light emitted by the light source may be a continuous spectrum or discrete wavelengths over a wavelength range from 150 to 2500 nm.

In some embodiments, the system may further comprise an illumination optical assembly disposed in the illumination path. The illumination optical assembly may be configured to collimate the light emitted by the light source.

In some embodiments, the polarization assembly may comprise a polarizer and a compensator for generating Mueller matrix elements corresponding to the one or more polarization states of the light emitted by the light source. The polarizer and the compensator may be arranged as rotating polarizer (RP), rotating compensator (RC), RPRC, or RCRC.

In some embodiments, the main objective may have a numerical aperture of 0.6 to 0.99 at the target. The main objective may have a magnification of 40× to 100×. The main objective may have a field of view of 15 μm to 350 μm.

In some embodiments, the system may further comprise a second objective collocated with the main objective. The second objective may be configured to transmit a portion of the light in ultraviolet wavelengths or deep ultraviolet wavelengths.

In some embodiments, the analyzer assembly may comprise an analyzer and a compensator for generating Mueller matrix elements corresponding to the one or more polarization states of the light reflected by the target.

In some embodiments, the detector may comprise a 2D CCD, a 2D photo diode array, or a combination of 1D sensors.

In some embodiments, the target may be a high aspect ratio structure.

In some embodiments, the processor may be configured to generate a measurement of the target based on a combination of beam profile reflectometry (BPR) data and spectroscopic ellipsometry (SE) or spectroscopic reflectometry (SR) data of a plurality of AOIs, a plurality of wavelengths, and a plurality of polarization states.

Another embodiment of the present disclosure provides a method. The method may comprise emitting light from a light source along an illumination path at one or more wavelengths, one or more angles of incidence (AOI), and one or more azimuths.

The method may further comprise polarizing the light into one or more polarization states with a polarization assembly disposed in the illumination path.

The method may further comprise focusing the light in the one or more polarization states with a main objective disposed in the illumination path.

The method may further comprise reflecting the light focused by the main objective from the illumination path to a collection path with a target.

The method may further comprise collecting the light reflected by the target with the main objective.

The method may further comprise analyzing one or more polarization states of the light reflected by the target with an analyzer assembly disposed in the collection path.

The method may further comprise detecting the light reflected by the target with a detector disposed in the collection path to generate an output signal based on the detected light.

The method may further comprise generating a measurement of the target with a processor in electronic communication with the detector based on the output signal produced at the one or more polarization states, the one or more wavelengths, the one or more AOIs, and the one or more azimuths.

### DESCRIPTION OF THE DRAWINGS

For a fuller understanding of the nature and objects of the disclosure, reference should be made to the following detailed description taken in conjunction with the accompanying drawings, in which:

FIG. 1 is a block diagram of a system according to an embodiment of the present disclosure;

FIG. 2 is a block diagram of a system according to another embodiment of the present disclosure; and

FIG. 3 is a flowchart of a method according to an embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process, step, and electronic changes may be made without departing from the scope of the disclosure. Accordingly, the scope of the disclosure is defined only by reference to the appended claims.

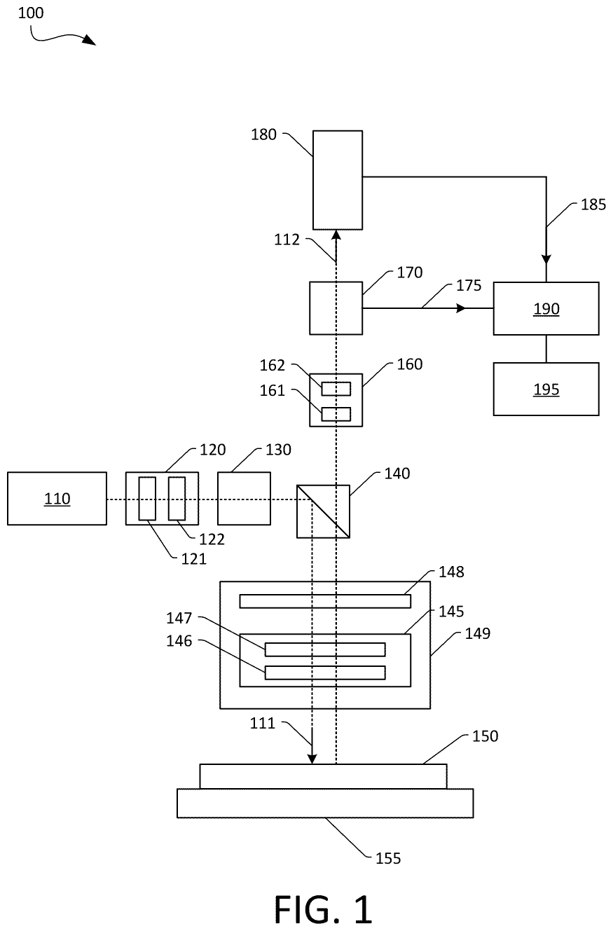

An embodiment of the present disclosure provides a system 100. The system 100 may be a metrology tool (e.g., a beam profile reflectometer (BPR)). In an instance, the system 100 in FIG. 1 may include an illumination system (e.g., light source 110), which illuminates a sample (e.g., target 150); a detector 180 which captures relevant information provided by the illumination system's interaction with the target 150, device, or feature on the sample; and a processor 190 which analyzes the information collected using one or more algorithms. The light source 110 may direct light at the sample at a first angle, and light can be reflected from the sample to the detector 180 at a second angle. The first and second angle may be same or different. The system 100 may capture measurements at thousands of different angles of incidence (AOI) and azimuths.

The light source 110 may be configured to emit light along an illumination path 111. The light emitted by the light source 110 may have a wavelength range of 150 to 2500 nm. In some embodiments, the light emitted by the light source 110 may have a wavelength range of 350 to 900 nm. The light source 110 may emit a continuous spectrum of light over the wavelength range or discrete wavelengths within the wavelength range. The light source 110 may be a laser, lamp, super continuum laser, globar, or laser sustained plasma (LSP) source. The light source 110 may be selected as being the brightest source over multiple wavelengths. For a wavelength range of 400 to 2500 nm, a super continuum laser may be used. In some embodiments, the system 100 may be a broad-band metrology tool, and the light source 110 may include a broad-band LSP source. The light source 110 may produce a beam of light with other sources or may use other techniques to measure a surface of a sample. The light source 110 may contain optics for conditioning the light and/or focusing the light.

The system 100 may further comprise an illumination optical assembly 120. The illumination optical assembly 120 may be disposed in the illumination path 111. The illumination optical assembly may be configured to collimate the light emitted by the light source 110. The illumination optical assembly 120 may comprise one or more pupils 121, field stops 122, lenses, mirrors, filters, apodizers, or beam conditioning optics for conditioning the light along the illumination path 111. In some embodiments, the illumination optical assembly 120 may include one or more optical elements having reflective optical power. Such optical elements may have one or more surfaces having reflective power and may be of various shapes (e.g., spherical, aspherical, etc.). For example, the optical elements may be mirrors having a flat, convex, or concave shape. The optical elements may be selected so that reflective power supports the wavelengths emitted by the light source 110, such as ultraviolet (UV) or other wavelengths. In other embodiments, the illumination optical assembly 120 may include one or more optical elements that are refractive or catadioptric. A combination of different optical elements may be selected based on the magnification, numerical aperture, and geometric requirements.

The system 100 may further comprise a polarization assembly 130. The polarization assembly 130 may be disposed in the illumination path 111. The polarization assembly 130 may be configured to receive the collimated light from the illumination optical assembly 120 and may be configured to produce one or more polarization states of the light. The polarization assembly 130 may comprise a polarizer and a compensator. The polarizer may be fixed or rotating. The compensator may be fixed or rotating. Accordingly, the polarization assembly 130 may support rotating polarizer (RP) and/or rotating compensator (RC) for generating Mueller matrix elements corresponding to the one or more polarization states of the light emitted by the light source 110. The polarization elements of the polarization assembly 130 may allow the system 100 to sample the target 150 at different polarization states, which can enhance measurement sensitivity and diversity.

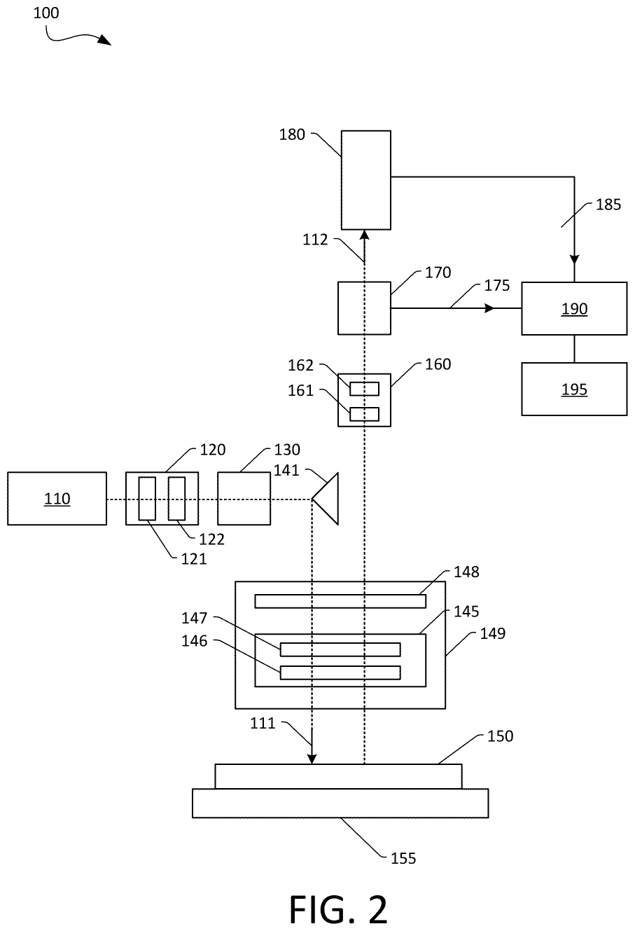

The system 100 may further comprise a beam splitter 140. The beam splitter 140 may be disposed in the illumination path 111 downstream of the polarization assembly 130. The beam splitter 140 may receive light in the one or more polarization states from the polarization assembly 130 and direct light toward the target 150. In an alternative embodiment shown in FIG. 2, the beam splitter 140 may be a knife edge mirror 141, which splits the beam of light in the illumination path 111 such that only 50% of the beam is directed toward the target.

The system 100 may further comprise a main objective 145. The main objective 145 may be disposed in the illumination path 111 downstream of the beam splitter 140. The main objective 145 may be configured to focus the light in the one or more polarization states onto the target 150. The main objective pupil 146 passes the light of a numerical aperture at target 150. The main objective field stop 147 passes the light of a field of view at target 150. The main objective 145 may have a numerical aperture of 0.6 to 0.99 at the target 150. For example, the numerical aperture may be 0.9. The main objective 145 may have a magnification of 40× to 100×. For example, the magnification may be 80× or 100×. The main objective 145 may have a field of view of 15 μm to 350 μm. For example, the field of view may be at least 15 μm, at least 30 μm, at least 50 μm, or at least 100 μm. Accordingly, the main objective 145 may provide a combination of high numerical aperture and high field of view for the light focused onto the target 150. The main objective 145 may be configured to transmit a wavelength range of 150 to 2500 nm. For example, the wavelength range may be 350 to 900 nm. The wavelength range may be a continuous spectrum or one or more discrete wavelengths transmissible by the main objective 145. The main objective 145 may be reflective, refractive, or catadioptric.

The system may further comprise a second objective 148. The second objective 148 may be collocated with the main objective 145 in the illumination path 111. The second objective 148 may be used to expand the wavelength range that is otherwise limited by a high numerical aperture main objective 145. For example, the second objective 148 may be configured to transmit a portion of the light in ultraviolet wavelengths or deep ultraviolet wavelengths. The second objective 148 may be reflective, refractive, or catadioptric.

The main objective 145 and second objective 148 may be part of an objective selector 149, which allows selection of two or more objectives to be placed in the illumination path 111. The objective selector 149 may be a turret or a slider that is configured to move the main objective 145 and/or the second objective 148 in or out of the illumination path 111. It should be understood that some single objectives may support a first wavelength range, while a different single object may support another wavelength range. With the combination of the main objective 145 and the second objective 148, a large numerical aperture and large wavelength range can be achieved. The objective selector 149 may comprise an adjustable field stop, where the field stop size may be adjusted based on the thickness of the target 150, the wavelength of the light emitted by the light source 110, and any stray light outside of the field of view.

The target 150 may be disposed in the illumination path 111. The target 150 may be configured to reflect the light focused by the illumination optical assembly 120 along a collection path 112. The target 150 may include a high aspect ratio structure on a substrate. A high aspect ratio structure may be a structure having 500 layers or more. For example, the target 150 may be flash memory on a semiconductor wafer. The target 150 may be disposed on a stage 155.

The light reflected along the collection path 112 may collected by the main objective 145. In some embodiments, the input and return beams of light may be collocated on the main objective 145. In other embodiments, the input and return beams may be spatially separated, where a first portion of the main objective 145 receives the illumination path 111, and a second portion of the main objective 145 receives the collection path. The light collected by the main objective 145 may be returned to the beam splitter 140. Alternatively, in the embodiment shown in FIG. 2, the light in the collection path 112 may be clear from the knife edge mirror 141.

The system 100 may further comprise a collection optical assembly 160. The collection optical assembly 160 may be disposed in the collection path 112. The beam splitter 140 may direct the light reflected from the target 150 toward the collection optical assembly 160. The collection optical assembly 160 may comprise one or more pupils 161, field stops 162, lenses, mirrors, filters, apodizers, or beam conditioning optics for conditioning the light along the collection path 112 to collect the light onto the detector 180. For example, the collection optical assembly may comprise a collection pupil 161 configured to collect the light reflected from the target 150. A position of the light collected on the collection pupil 161 may correspond to a subset of the one or more AOIs and the one or more azimuths. In other words, by changing the AOI or azimuth, the position of the light collected on the collection pupil 161 may change, so as to produce a two-dimensional image. In the embodiment shown in FIG. 2, the collection pupil 161 only receives half of the AOIs and azimuths from the target 150, as the knife edge mirror 141 directs only half of the light from the light source 110 through the main objective 145 toward the target 150. In some embodiments, the collection optical assembly 160 may include one or more optical elements having reflective optical power. Such optical elements may have one or more surfaces having reflective power and may be of various shapes (e.g., spherical, aspherical, etc.). For example, the optical elements may be mirrors having a flat, convex, or concave shape. The optical elements may be selected so that reflective power supports the wavelengths emitted by the light source 110, such as ultraviolet (UV) or other wavelengths. In other embodiments, the collection optical assembly 160 may include one or more optical elements that are refractive or catadioptric. A combination of different optical elements may be selected based on the magnification, numerical aperture, and geometric requirements.

The system may further comprise an analyzer assembly 170. The analyzer assembly 170 may be disposed in the collection path 112. The analyzer assembly 170 can be disposed after the collection optical assembly 160 (as shown in FIG. 1) or before the collection optical assembly 160 in the collection path 112. The beam splitter 140 may direct the light reflected from the target 150 toward the analyzer assembly 170. In the embodiment shown in FIG. 2, the knife edge mirror 141 only reflects half of the beam of light in the illumination path 111 toward the target 150, and the collection path 112 passes by the knife edge mirror 141, so the analyzer assembly 170 only receives the half of the beam of light reflected by the target 150. The analyzer assembly 170 may be configured to analyze one or more polarization states of the light reflected from the target 150. The analyzer assembly 170 may generate polarization data 175 from the analyzed light. The analyzer assembly 170 may comprise an analyzer and a compensator. The analyzer may be fixed or rotating. The compensator may be fixed or rotating. Accordingly, the analyzer assembly 170 may support rotating polarizer (RP) and/or rotating compensator (RC) for generating Mueller matrix elements corresponding to the one or more polarization states of the light reflected by the target 150. The combination of the polarization assembly 130 and the analyzer assembly 170 may support RP, RC, RPRC, and or RCRC, based on the combinations of rotating or fixed polarizers and compensators of the two assemblies.

The detector 180 may be disposed in the collection path 112. The detector 180 may be configured to detect the light reflected by the target 150. For example, the detector 180 may detect the light imaged on the collection pupil 161. The detector 180 may resolve the light reflected from the target 150 in one or more segments, where each segment corresponds a subset of the one or more AOIs and the one or more azimuths. The detector 180 may be further configured to generate an output signal 185 based on the detected light. The detector 180 may be a 2D charge coupled device (CCD), a 2D sensor, or a photo diode array. The detector 180 may be comprised of one or more 1D arrays. The detector 180 may comprise separate detectors for different wavelengths of light (e.g., UV and IR). The detector 180 may use any other types of fast 1D and 2D sensors.

The processor 190 can communicate with the analyzer assembly 170, the detector 180, or other components of the system 100. The processor 190 may be implemented in practice by any combination of hardware, software, and firmware. Also, its functions as described herein may be performed by one unit, or divided up among different components, each of which may be implemented in turn by any combination of hardware, software, and firmware. Program code or instructions for the processor 190 to implement various methods and functions may be stored in controller readable storage media, such as a memory in an electronic data storage unit 195 in electronic communication with the processor 190, within the processor 190, external to the processor 190, or combinations thereof.

The processor 190 may be coupled to the components of the system 100 in any suitable manner (e.g., via one or more transmission media, which may include wired and/or wireless transmission media) such that the processor 190 can receive the output generated by the system 100, such as output from the analyzer assembly 170 and the detector 180. The processor 190 may be configured to perform a number of functions using the output. For instance, the processor 190 may be configured to generate a measurement of the target 150 based on the polarization data 175 and the output signal 185. The measurement may comprise one or more of critical dimension (CD), single-wire aggregation (SWA), shape, stress, composition, films, bandgap, electrical properties, focus/dose, overlay, generating process parameters (e.g., resist state, partial pressure, temperature, focusing model), and/or any combination thereof. The processor 190 may be configured to send the output to an electronic data storage unit 195 or another storage medium without reviewing the output. The processor 190 may be further configured as described herein. Using BPR data or a combination of BPR and SE/SR data collected by the system 100, a data cube of measurements taken at many wavelengths, polarization states, and angles can be collected. A “data cube” refers to a multi-dimensional array of information, where the cell values correspond to measurements varied in each dimension. The data cube can be fitted to a model to identify variations caused by process errors, and the process can be adjusted to reduce variations.

The processor 190, other system(s), or other subsystem(s) described herein may take various forms, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high speed processing and software, either as a standalone or a networked tool. For example, the processor 190 may include a microprocessor, a microcontroller, or other devices.

The processor 190 may be in electronic communication with the detector 180 or other components of the system 100. The processor 190 may be configured according to any of the embodiments described herein. The processor 190 also may be configured to perform other functions or additional steps using the output of the detector 180 or using images, measurements, or data from other sources.

The system 100 can provide information about the target 150 or can provide information used to form images of the target 150. In particular, the system 100 can be configured to provide one or more of rotating polarizer data, rotating compensator spectroscopic ellipsometry data; full Mueller matrix components data; rotating polarizer spectroscopic ellipsometry data; reflectometry data; laser-driven spectroscopic reflectometry data; or X-ray data. In an instance, the system 100 provides spectroscopic ellipsometry using a broadband light source, the detector 180 measures how the light source interacts with the target, and processing algorithms that extract the relevant parameters of the target. In another instance, the light source 110 may be a LSP source, which can provide high intensities and increase the signal-to-noise ratio at the detector, as opposed to a Xe lamp. To enhance target signatures, the system 100 may use N₂ or Ar gas purge to extend the wavelength range to 170 nm or below.

The system 100 can comprise one or more hardware configurations which may be used in conjunction with certain embodiments of this invention to, for example, measure the various aforementioned semiconductor structural and material characteristics. Examples of such hardware configurations include, but are not limited to, a spectroscopic ellipsometer (SE), an SE with multiple angles of illumination, an SE measuring Mueller matrix elements (e.g. using rotating compensator(s)), a single-wavelength ellipsometer, a beam profile ellipsometer (angle-resolved ellipsometer), a beam profile reflectometer (angle-resolved reflectometer), a broadband reflective spectrometer (spectroscopic reflectometer), a single-wavelength reflectometer, an angle-resolved reflectometer, an imaging system, or a scatterometer (e.g. speckle analyzer).

The hardware configurations can be separated into discrete operational systems. One or more hardware configurations can be combined into a single tool. U.S. Pat. No. 7,933,026, which is hereby incorporated by reference in its entirety, provides an example. There are typically numerous optical elements in such systems, including certain lenses, collimators, mirrors, quarter-wave plates, polarizers, detectors, cameras, apertures, and/or light sources. The wavelengths for optical systems can vary from about 120 nm to 3 microns. For non-ellipsometer systems, signals collected can be polarization-resolved or unpolarized. Multiple metrology tools also can be used for measurements on a single or multiple metrology targets, such as described in U.S. Pat. No. 7,478,019, which is incorporated by reference in its entirety.

The illumination system of the certain hardware configurations can include one or more light sources. The light source may generate light having only one wavelength (i.e., monochromatic light), light having a number of discrete wavelengths (i.e., polychromatic light), light having multiple wavelengths (i.e., broadband light) and/or light the sweeps through wavelengths, either continuously or hopping between wavelengths (e.g., using tunable sources or swept source). Examples of suitable light sources include a white light source, an ultraviolet (UV) laser, an arc lamp or an electrode-less lamp, a laser sustained plasma (LSP) source, a supercontinuum source (such as a broadband laser source), or shorter-wavelength sources such as x-ray sources, extreme UV sources, or some combination thereof. The light source may also be configured to provide light having sufficient brightness, which in some cases may be a brightness greater than about 1 W/(nm cm² Sr). The system 100 also can include a fast feedback to the light source for stabilizing its power and wavelength. Output of the light source can be delivered via free-space propagation, or in some cases delivered via optical fiber or light guide of any type.

The system 100 can be designed to make many different types of measurements related to semiconductor manufacturing. For example, the system 100 can measure characteristics of one or more targets, such as critical dimensions, overlay, sidewall angles, film thicknesses, process-related parameters (e.g., focus and/or dose). The targets can include certain regions of interest that are periodic in nature, such as for example gratings in a memory die. Targets can include multiple layers (or films) whose thicknesses can be measured by the metrology tool. Targets can include target designs placed (or already existing) on the semiconductor wafer for use, such as with alignment and/or overlay registration operations. Certain targets can be located at various places on the semiconductor wafer. For example, targets can be located within the scribe lines (e.g., between dies) and/or located in the die itself. In certain embodiments, multiple targets are measured (at the same time or at differing times) by the same or multiple metrology tools. The data from such measurements may be combined. Data from the system 100 can be used in the semiconductor manufacturing process for example to feed-forward, feed-backward and/or feed-sideways corrections to the process (e.g., lithography or etch).

As semiconductor device pattern dimensions continue to shrink, smaller metrology targets are often required. Furthermore, the measurement accuracy and matching to actual device characteristics can increase the need for device-like targets as well as in-die and even on-device measurements. For example, focused beam ellipsometry based on primarily reflective optics can be used. Apodizers can be used to mitigate the effects of optical diffraction causing the spread of the illumination spot beyond the size defined by geometric optics. High-numerical-aperture tools with simultaneous multiple angle-of-incidence illumination can be used to achieve small-target capability.

Other measurement examples can include measuring the composition of one or more layers of the semiconductor stack, measuring certain defects on (or within) the wafer, or measuring the amount of photolithographic radiation exposed to the wafer. In some cases, the system 100 and algorithm may be configured for measuring non-periodic targets.

In addition, there are typically numerous optical elements in such systems, including certain lenses, collimators, mirrors, quarter-wave plates, polarizers, detectors, cameras, apertures, and/or light sources. The wavelengths for optical systems can vary from about 120 nm to 3 microns. For non-ellipsometer systems, signals collected can be polarization-resolved or unpolarized. Multiple metrology heads can be integrated on the same tool. However, in many cases, multiple metrology tools are used for measurements on a single or multiple metrology targets.

Measurement of parameters of interest usually involves multiple algorithms. For example, optical interaction of the incident beam with the sample is modeled using an electro-magnetic (EM) solver and uses such algorithms as rigorous coupled wave analysis (RCWA), finite element modeling (FEM), method of moments, surface integral method, volume integral method, finite-difference time domain (FDTD), and others. The target of interest is usually modeled (parametrized) using a geometric engine a process modeling engine, or a combination of both. A geometric engine is implemented, for example, in the AcuShape software product from KLA Corporation.

Collected data can be analyzed by a number of data fitting and optimization techniques an technologies including libraries, fast-reduced-order models, regression, machine-learning algorithms, principal component analysis (PCA), independent component analysis (ICA), local-linear embedding (LLE), sparse representation such as Fourier or wavelet transform, a Kalman filter, algorithms to promote matching from same or different tool types, or others. Collected data can also be analyzed by algorithms that do not include modeling, optimization and/or fitting.

Computational algorithms are usually optimized for metrology applications with one or more approaches being used such as design and implementation of computational hardware, parallelization, distribution of computation, load-balancing, multi-service support, or dynamic load optimization. Different implementations of algorithms can be done in firmware, software, FPGA, programmable optics components, etc.

The data analysis and fitting steps can have one or more objectives. Critical dimension, sidewall angle, shape, stress, composition, films, bandgap, electrical properties, focus/dose, overlay, generating process parameters (e.g., resist state, partial pressure, temperature, focusing model), and/or any combination thereof can be measured or otherwise determined. Metrology systems can be modeled or designed. Metrology targets also can be modelled, designed, and/or optimized.

Embodiments of the present disclosure address the field of semiconductor metrology and are not limited to the hardware, algorithm/software implementations and architectures, and use cases summarized above.

With the system 100 of the present disclosure, the measurements of the target 150 may have higher diversity, accuracy, precision, sensitivity, signal fidelity and faster time to results for thick films and HAR structures. For example, the system 100 may capture measurements over a wide range of angles, complementary to SE and SR spectrum data. Generating Mueller matrix elements in response to different polarization states may provide additional data. Furthermore, a wide field of view of the main objective 145 may preserve signal fidelity and avoid beam clipping of high AOI light in thick stacks. The system 100 uses BPR data or a combination of BPR and SE/SR data to provide a data cube of measurements taken at many wavelengths, polarization states, and angles, which allows for greater measurement diversity and faster time to results that were not previously available in existing systems.

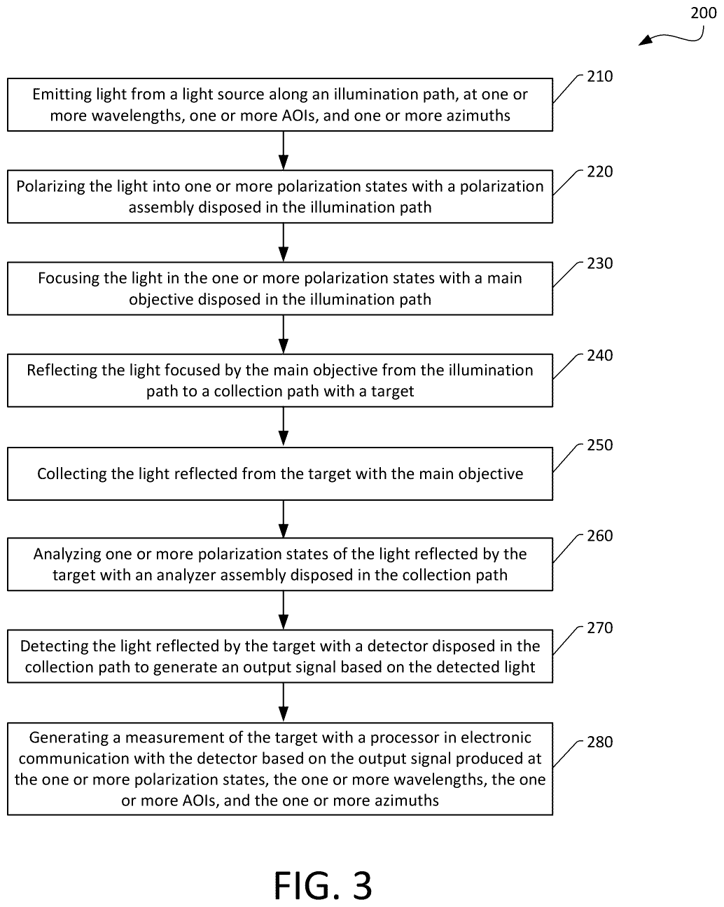

An embodiment of the present disclosure provides a method 200. The method 200 may be applied to a metrology tool, such as the system 100 described above. As shown in FIG. 3, the method 200 may comprise the following steps.

At step 210, light is emitted from a light source along an illumination path at one or more wavelengths, one or more angles of incidence (AOI), and one or more azimuths. The light emitted by the light source may have a wavelength range of 150 to 2500 nm. In some embodiments, the light emitted by the light source may have a wavelength range of 350 to 900 nm. The light source may emit a continuous spectrum of light over the wavelength range or discrete wavelengths within the wavelength range. The light source may be a laser, lamp, globar, super continuum laser or LSP source. The light source may be selected as being the brightest source over multiple wavelengths. For a wavelength range of 400 to 2500 nm, a super continuum laser may be used. In some embodiments, the method 200 may be applied to a broad-band plasma tool, and the light source may include a broad-band plasma source. The light source may produce a beam of light with other sources or may use other techniques to measure a surface of a sample.

In some embodiments, the light may be collimated in the illumination path with an illumination optical assembly disposed in the illumination path. The illumination optical assembly may comprise one or more pupils, field stops, lenses, mirrors, filters, apodizers, or beam conditioning optics for conditioning the light along the illumination path and/or focusing the light onto the target. In some embodiments, the illumination optical assembly may include one or more optical elements having reflective optical power. Such optical elements may have one or more surfaces having reflective power and may be of various shapes (e.g., spherical, aspherical, etc.). For example, the optical elements may be mirrors having a flat, convex, or concave shape. The optical elements may be selected so that reflective power supports the wavelengths emitted by the light source, such as ultraviolet (UV) or other wavelengths. In other embodiments, the illumination optical assembly may include one or more optical elements that are refractive or catadioptric. A combination of different optical elements may be selected based on the magnification, numerical aperture, and geometric requirements.

At step 220, the light is polarized into one or more polarization states with a polarization assembly disposed in the illumination path. The polarization assembly may comprise a polarizer and a compensator. The polarizer may be fixed or rotating. The compensator may be fixed or rotating. Accordingly, the polarization assembly may support rotating polarizer (RP) and/or rotating compensator (RC) for generating Mueller matrix elements corresponding to the one or more polarization states of the light emitted by the light source. The polarization elements of the polarization assembly may allow the target to be sampled at different polarization states, which can enhance measurement sensitivity and diversity.

At step 230, the light is focused in the one or more polarization states with a main objective disposed in the illumination path.

At step 240, the light focused by the main objective is reflected from the illumination path to a collection path with a target. The main objective may be disposed in the illumination path downstream of the polarization assembly. A beam splitter may be disposed in the illumination path between the polarization assembly and the main objective, which may receive the light in the one or more polarization states from the polarization assembly and may combine the light in a common path toward the target. The main objective may have a numerical aperture of 0.6 to 0.99 at the target. For example, the numerical aperture may be 0.9. The main objective may have a magnification of 40× to 100×. For example, the magnification may be 80× or 100×. The main objective may have a field of view of 15 μm to 350 μm. For example, the field of view may be at least 15 μm, at least 30 μm, at least 50 μm, or at least 100 μm. Accordingly, the main objective may provide a combination of high numerical aperture and high field of view for the light focused onto the target. The main objective may be configured to transmit a wavelength range of 150 to 2500 nm. For example, the wavelength range may be 350 to 900 nm. The wavelength range may be a continuous spectrum or one or more discrete wavelengths transmissible by the main objective. The main objective may be reflective, refractive, or catadioptric. The target may include a high aspect ratio structure on a substrate. A high aspect ratio structure may be a structure having 500 layers or more. For example, the target may be flash memory on a semiconductor wafer. The target may be disposed on a stage.

In some embodiments, a second objective collocated with the main objective in the illumination path may be configured to transmit a portion of the light in ultraviolet wavelengths or deep ultraviolet wavelengths. The second objective 148 may be reflective, refractive, or catadioptric. The main objective and second objective may be part of an objective selector, which allows selection of two or more objectives to be placed in the illumination path. The objective selector may be a turret or a slider that is configured to move the main objective and/or the second objective in or out of the illumination path. With the combination of the main objective and the second objective, a large numerical aperture and large wavelength range can be achieved. The objective selector may comprise an adjustable field stop, where the field stop size may be adjusted based on the thickness of the target, the wavelength of the light emitted by the light source, and any stray light outside of the field of view.

At step 250, the light reflected by the target is collected with the main objective. In some embodiments, the input and return beams of light may be collocated on the main objective. In other embodiments, the input and return beams may be spatially separated, where a first portion of the main objective receives the illumination path, and a second portion of the main objective receives the collection path. The light collected by the main objective may be returned to the beam splitter.

In some embodiments, a collection optical assembly may be disposed in the collection path, which is configured to receive the light reflected by the target. The beam splitter may direct the light reflected from the target toward the collection optical assembly. The collection optical assembly may comprise one or more pupils, field stops, lenses, mirrors, filters, apodizers, or beam conditioning optics for conditioning the light along the collection path to collect the light onto the detector. For example, the collection optical assembly may comprise a collection pupil configured to collect the light reflected from the target. A position of the light collected on the collection pupil may correspond to a subset of the one or more AOIs and the one or more azimuths. In other words, by changing the AOI or azimuth, the position of the light collected on the collection pupil may change, so as to produce a two-dimensional image. In some embodiments, the collection optical assembly may include one or more optical elements having reflective optical power. Such optical elements may have one or more surfaces having reflective power and may be of various shapes (e.g., spherical, aspherical, etc.). For example, the optical elements may be mirrors having a flat, convex, or concave shape. The optical elements may be selected so that reflective power supports the wavelengths emitted by the light source 110, such as ultraviolet (UV) or other wavelengths. In other embodiments, the collection optical assembly may include one or more optical elements that are refractive or catadioptric. A combination of different optical elements may be selected based on the magnification, numerical aperture, and geometric requirements.

At step 260, one or more polarization states of the light reflected by the target with are analyzed with an analyzer assembly disposed in the collection path. The beam splitter may direct the light reflected from the target toward the analyzer assembly. The analyzer assembly may comprise an analyzer and a compensator. The analyzer may be fixed or rotating. The compensator may be fixed or rotating. Accordingly, the polarization assembly 130 may support rotating polarizer (RP) and/or rotating compensator (RC) for generating Mueller matrix elements corresponding to the one or more polarization states of the light reflected by the target. The combination of the polarization assembly and the analyzer assembly may support RP, RC, RPRC, and or RCRC, based on the combinations of rotating or fixed polarizers and compensators of the two assemblies.

At step 270, the light reflected by the target is detected with a detector disposed in the collection path to generate an output signal based on the detected light. For example, the detector may detect the light imaged on the collection pupil. The detector may resolve the light reflected from the target in one or more segments, where each segment corresponds a subset of the one or more AOIs and the one or more azimuths. The detector may be a 2D charge coupled device (CCD), a 2D sensor, or a photo diode array. The detector may be comprised of one or more 1D arrays. The detector may comprise separate detectors for different wavelengths of light (e.g., UV and IR). The detector may use any other types of fast 1D and 2D sensors.

At step 280, a measurement of the target is generated with a processor in electronic communication with the detector based on the output signal produced at the one or more polarization states, the one or more wavelengths, the one or more AOIs, and the one or more azimuths. The measurement may comprise one or more of critical dimension (CD), single-wire aggregation (SWA), shape, stress, composition, films, bandgap, electrical properties, focus/dose, overlay, generating process parameters (e.g., resist state, partial pressure, temperature, focusing model), and/or any combination thereof. The processor may be configured to send the output to an electronic data storage unit or another storage medium without reviewing the output. Using BPR data or a combination of BPR and SE/SR data, a data cube of measurements taken at many wavelengths, polarization states, and angles can be collected. A “data cube” refers to a multi-dimensional array of information, where the cell values correspond to measurements varied in each dimension. The data cube can be fitted to a model to identify variations caused by process errors, and the process can be adjusted to reduce variations.

With the method 200 of the present disclosure, the measurements of the target may have higher diversity, accuracy, precision, sensitivity, signal fidelity, and faster time to results for thick films and HAR structures. For example, the measurements may be captured over a wide range of angles, complementary to SE and SR spectrum data. Generating Mueller matrix elements in response to different polarization states may provide additional data. Furthermore, a wide field of view of the main objective may preserve signal fidelity and avoid beam clipping of high AOI light in thick stacks. The method 200 uses BPR data or a combination of BPR and SE/SR data to provide a data cube of measurements taken at many wavelengths, polarization states, and angles, which allows for greater measurement diversity and faster time to results that were not previously available with existing methods.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a light source configured to emit light along an illumination path at one or more wavelengths, one or more angles of incidence (AOI), and one or more azimuths;
a polarization assembly disposed in the illumination path, wherein the polarization assembly is configured to produce one or more polarization states of the light;
a main objective disposed in the illumination path and configured to focus the light in the one or more polarization states onto a target, wherein the target is configured to reflect the light along a collection path and the main objective is further configured to collect the light reflected from the target;
an analyzer assembly disposed in the collection path, wherein the analyzer assembly is configured to analyze one or more polarization states of the light reflected from the target;
a detector disposed in the collection path, wherein the detector is configured to detect the light reflected from the target and generate an output signal based on the detected light; and
a processor in electronic communication with the detector, wherein the processor is configured to generate a measurement of the target based on the output signal produced at the one or more polarization states, the one or more wavelengths, the one or more AOIs, and the one or more azimuths.

2. The system of claim 1, further comprising a collection pupil disposed in the collection path and configured to collect the light reflected from the target, wherein an x-y position of the light collected on the collection pupil corresponds to a subset of the one or more AOIs and the one or more azimuths.

3. The system of claim 2, wherein the detector is conjugate with the collection pupil, such that the detector is configured to image each x-y position of the light collected on the collection pupil.

4. The system of claim 1, wherein the one or more wavelengths of light emitted by the light source are a continuous spectrum or discrete wavelengths over a wavelength range from 150 to 2500 nm.

5. The system of claim 1, further comprising an illumination optical assembly disposed in the illumination path, wherein the illumination optical assembly is configured to collimate the light emitted by the light source.

6. The system of claim 1, wherein the polarization assembly comprises a polarizer and a compensator for generating Mueller matrix elements corresponding to the one or more polarization states of the light emitted by the light source, wherein the polarizer and the compensator are arranged as rotating polarizer (RP), rotating compensator (RC), RPRC, or RCRC.

7. The system of claim 1, wherein the main objective has a numerical aperture of 0.6 to 0.99 at the target.

8. The system of claim 1, wherein the main objective has a magnification of 40× to 100×.

9. The system of claim 1, wherein the main objective has a field of view of 15 μm to 350 μm.

10. The system of claim 1, further comprising a second objective collocated with the main objective, wherein the second objective is configured to transmit a portion of the light in ultraviolet wavelengths or deep ultraviolet wavelengths.

11. The system of claim 1, wherein the analyzer assembly comprises an analyzer and a compensator for generating Mueller matrix elements corresponding to the one or more polarization states of the light reflected by the target.

12. The system of claim 1, wherein the detector comprises a 2D CCD, a 2D photo diode array, or a combination of 1D sensors.

13. The system of claim 1, wherein the target is a high aspect ratio structure.

14. The system of claim 1, wherein the processor is configured to generate a measurement of the target based on a combination of beam profile reflectometry (BPR) data and spectroscopic ellipsometry (SE) or spectroscopic reflectometry (SR) data of a plurality of AOIs, a plurality of wavelengths, and a plurality of polarization states.

15. A method comprising:
emitting light from a light source along an illumination path at one or more wavelengths, one or more angles of incidence (AOI), and one or more azimuths;
polarizing the light into one or more polarization states with a polarization assembly disposed in the illumination path;
focusing the light in the one or more polarization states with a main objective disposed in the illumination path;
reflecting the light focused by the main objective from the illumination path to a collection path with a target;
collecting the light reflected by the target with the main objective;
analyzing one or more polarization states of the light reflected by the target with an analyzer assembly disposed in the collection path;
detecting the light reflected by the target with a detector disposed in the collection path to generate an output signal based on the detected light; and
generating a measurement of the target with a processor in electronic communication with the detector based on the output signal produced at the one or more polarization states, the one or more wavelengths, the one or more AOIs, and the one or more azimuths.

16. The method of claim 15, wherein the one or more wavelengths of light emitted by the light source are a continuous spectrum or discrete wavelengths over a wavelength range from 150 to 2500 nm.

17. The method of claim 15, wherein the main objective has a numerical aperture of 0.6 to 0.99 at the target.

18. The method of claim 15, wherein the main objective has a magnification of 40× to 100×.

19. The method of claim 15, wherein the main objective has a field of view of 15 μm to 350 μm.

20. The method of claim 15, wherein a collection pupil disposed in the collection path is configured to collect the light reflected from the target, wherein an x-y position of the light collected on the collection pupil corresponds to a subset of the one or more AOIs and the one or more azimuths, and the detector is conjugate with the collection pupil, such that the detector images each x-y position of the light collected on the collection pupil to generate a corresponding output signal.

21. The method of claim 15, wherein the target is a high aspect ratio structure.
